(19) United States
(12) Patent Application Publication
(10) Pub. No.: US 2017/0086314 A1
(43) Pub. Date: Mar. 23, 2017

(54) Elevating Support For Viewing Electronic Displays

(71) Applicant: David F. Simon, Lakeland, FL (US)

(72) Inventor: David F. Simon, Lakeland, FL (US)

(21) Appl. No.: 15/271,275

(22) Filed: Sep. 21, 2016

Related U.S. Application Data
(60) Provisional application No. 62/222,291, filed on Sep. 23, 2015.

(51) Int. Cl. H05K 5/02; F16M 11/20; F16M 11/28; F16B 2/06; F16M 11/40; F16M 11/04; F16B 1/00; A47B 23/00; F16B 7/14

(52) U.S. Cl. CPC H05K 5/0204; A47B 23/007; F16M 11/2021; F16M 11/28; F16B 7/14; F16M 11/40; F16M 11/041; F16B 1/00; F16M 11/2078; F16B 2/06; H05K 5/0217; F16B 2001/0035

(57) ABSTRACT

An adjustable support for holding an electronic device having a display at a desired elevated position for viewing of the display without tilting of the user's head. The support includes an upright elongated member pivotally connected to a generally planar base piece held beneath the user's thigh so as to hold the pivotally connected elongated member in an upright position. A telescoping and gooseneck segment enhance the adjustability of the position of the upright member at level and orientation enabling easy viewing of the display without tipping the head of a seated or reclining user. A magnetic or clamping cradle adjacent an upper end of the upright member by a ball joint engages the electronic device, with the ball joint providing adjustment of the orientation of the electronic device.

### CROSS REFERENCE TO RELATED APPLICATIONS

This application claims the benefit of U.S. provisional application No. 62/222,291 filed on Sep. 23, 2015.

### BACKGROUND OF THE INVENTION

This invention concerns a support for hand held electronic devices which have display screens for viewing text, drawings, photos, movies, etc., such as smart phones and tablets.

The usual way for viewing such devices is to hold the device positioned in the vicinity of the person's lap or waist so that the person must tilt his or her head downwardly to view the display screen and any keyboard provided.

Commonly, such position is assumed by the user for long periods of time.

Sustained tilted neck positioning causes undesirable stress on one's spine particularly in the upper part thereof. The human head has a significant weight when compared to the load capacity of the spine. In a standing or seated position with the spine near vertical, the human spine is designed to best support the head when both the spine and neck are aligned. When the neck is inclined for lengthy periods, the weight of the head exerts an excessive undesirable stress on the spine nick section. This stress may cause pain and even injury to a person's spine such that the person develops a stooped posture, which posture further stresses the person's spine. In fact, the medical community is diagnosing such conditions in people as young as 14 years, commonly referred to as “TechNeck” or “TextNeck”.

It is an object of the present invention to provide a convenient support arrangement that positions a smart phone or other similar electronic device at an elevated level for viewing of the display so that it can be done while their head and spine are more nearly aligned to better support the weight of the head and thus reduce or eliminate this condition.

It has become a widespread practice to take photos or video with such devices, and it would also be advantageous, particularly when taking “selfies” or photos of a person holding the device to provide a steady support for the device, as it is commonly done when taking pictures with conventional cameras. This has most often been provided by a tripod or similar supporting structure.

However, selfies are often taken when a person is out and about and tripods are usually deemed to be too bulky to be carried. Another disadvantage of the tripod is that the inclined legs create obstacles when the person or subject attempts to be positioned close to the device, as for reading when seated in a chair or reclining in a bed or sofa. Furthermore, conventional tripods offer only limited capability to adjust the position or orientation of the device.

The present inventor has developed a swing arm support, as described and claimed in U.S. Pat. No. 9,140,406 sold under the trademark LEVO which has a great capacity to stably hold such devices in a multitude of locations and orientations, but this device is also not adapted to be carried about by a user, but rather is intended to remain in a home, office, etc for use in those settings.

It is an object to provide a portable elevating support which conveniently enables positioning of such electronic devices so as to be held at an elevated level not requiring the user to tilt his or her head in order to view the associated display while being lightweight and easily transported by the user for use anywhere, and does not impede positioning of the device close to the subject or picture taken.

### SUMMARY OF THE INVENTION

The above recited objects and other objects of the invention which will be understood by those skilled in the art are accomplished by an easily carried elevating support for an electronic device including an upright elongated member mounting a cradle for holding the electronic device to enable holding the device an elevated location with respect to user to eliminate the need to tilt the neck to view the display device.

The elevating support further includes a base piece which is configured to be received and held under the thigh of a seated (or reclining) user. The upright member is pivotally connected to a side perimeter of the base piece so as to be held able to be extended vertically with the user's body weight holding the base piece stationary. The base piece is preferably well padded so that the user can remain comfortable when seated (or reclined) for extended periods with his or her thigh remaining atop the base piece. A slight valley contour occupied by thigh securely hold the piece to prevent inadvertent shifting at the base piece.

Preferably, the upright member is comprised of a rigid telescoping lower section pivotally connected at its lower end project up from one side of the base piece. The upright member also preferably may include an upper gooseneck section connected at a lower end to the upper end of the telescoped section. An angled arm can be used instead of a gooseneck for greater durability such as an angled arm.

The pivoted connection of the upright member to the base piece allows swinging of the support forwardly towards the seated user or rearwardly away from the seated user, or downwardly or upwardly from a reclining user.

The gooseneck section or angled arm allows adjustment of the position in any direction of a device cradle detachably connected to the upper end of the gooseneck section of the upright member.

The cradle can include a plate equipped with one or more magnets attracted to a ferromagnetic plate attached to the back of the device or a case for the device to be detachably connected thereto.

The cradle can also comprise an adjustable clamping holder, engaging the sides of the device or its case with a moderate squeezing pressure.

The cradle of either type connected adjacent the upper end of the upright member with a ball joint to allow swiveling of the supported device and afford additional adjustability of the orientation of the held device.

### DESCRIPTION OF THE DRAWING FIGURES

FIG. 1 is a pictorial view of an elevating support according to the invention and a fragmentary portion of a chair or bench on which a user can be seated with the base piece included in the support held stationary by being located beneath his or her thigh by the user's body weight.

FIG. 2 is a side elevational view of the elevating support shown in FIG. 1, with a telescoping section of an elongated upright member included in the support in a retracted state and a cradle separated from the upper end of the upright elongated member and an electronic device in a case to be held in the cradle separated therefrom as shown.

FIG. 3 is a view from the top of the elevated support shown in FIGS. 1 and 2 with a magnetic cradle assembled to the upright member.

FIG. 4 is an enlarged exploded pictorial view of the magnetic cradle shown in FIGS. 1-3 and a fragmentary top end of the elongated upright member associated therewith, and an electronic device without a case to be held therein.

FIG. 5 is an elevational end view of the pivotal connection of the lower end of an elongated upright member, shown in fragmentary portion, to a base piece also shown in fragmentary form.

FIG. 6 is a pictorial exploded view of a clamping cradle and ball connection components used to be connected to a ball connected to the top of the upright support and electronic device indicating an adjustable width capability.

FIG. 7 is a reverse pictorial view of the clamping cradle shown in FIG. 6 with an electronic device installed thereon.

FIG. 8 is a fragmentary pictorial view of an attachment of the upright support to the base piece.

FIG. 9 is a fragmentary pictorial view of an angled arm substituted for the gooseneck section in an alternative embodiment.

### DETAILED DESCRIPTION

In the following detailed description, certain specific terminology will be employed for the sake of clarity and a particular embodiment described in accordance with the requirements of 35 USC 112, but it is to be understood that the same is not intended to be limiting and should not be so construed inasmuch as the invention is capable of taking many forms and variations within the scope of the appended claims.

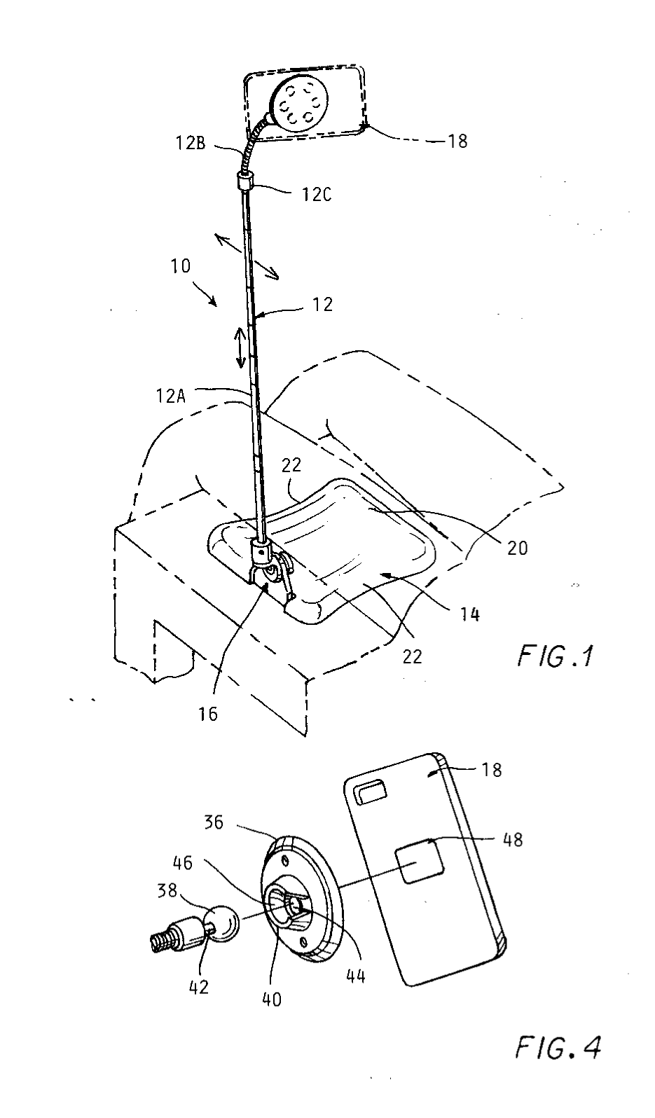

Referring to the drawings and particularly FIG. 1, an elevating support 10 according to one embodiment of the invention is shown in use by a seated user. The support 10 includes an elongated upright member 12, connected to a base piece 14 by a pivotal connection 16 to one side of the base piece 14.

The pivotal connection 16 allows the upright member 12 to be swung in a plane extending alongside the user or away from the user to obtain a desired location of an electronic device 18, shown in broken lines held adjacent the upper end of the upright member 12.

Such swinging motion is limited to be in the plane by the design of the connection as described in detail thereinafter. A frictional engagement of elements in the pivotal connection 16 causes the upright member to remain in any adjusted position, as further described below.

Such swinging motion allows adjustment of the height and the distance the device 18 is located in front of the user.

The base piece 14, which may be generally rectangular is configured to allow a user to extend one thigh across the upper surface thereof and to comfortably remain in that position for long periods.

A shallow front to rear aligned slightly curved valley 20 will engage the person's thigh and advantageously inhibit skewing of the base piece 14 and thereby provide a secure positioning of the upright member in the plane of swinging motion. The weight of the person's leg effectively preventing such shifting.

The base piece 14 surface can be defined by padding for the user's comfort, and shallow scallops 22 at the front and rear sides also aid in achieving a comfortable engagement with the leg while resisting any tipping of the upright member 12.

The upright member 12 is advantageously made up of two sections, a lowermost telescoping section 12A, shown fully extended in FIG. 1 which conventionally allows setting of a desired height of the held device 18 by extending the segments thereof.

A gooseneck section 12B is coupled to the top of the telescopic section 12A to afford unidirectional adjustment of the position of the held device 18.

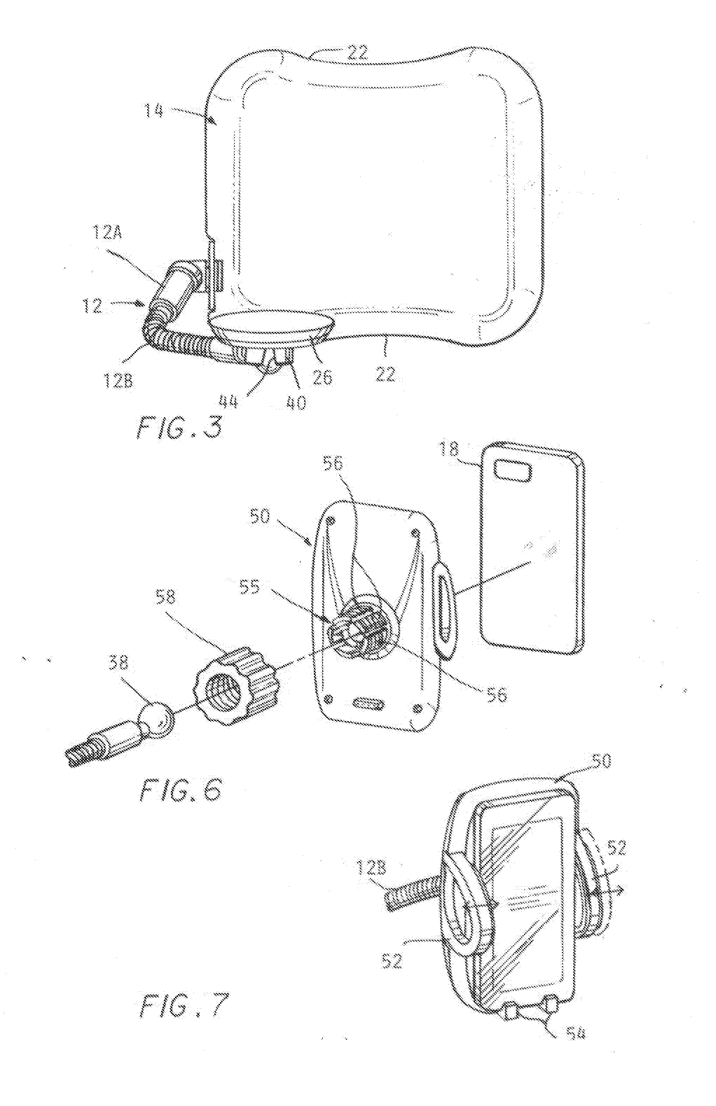

FIG. 3 shows details of the pivotal connection 16 between the base piece 14 and upright member 12, which includes an angle piece 24 nonrotatably attached to a bottom anchor sleeve 26 of the upright member 12.

A downwardly extending leg 24A of the angle piece 24 receives a head pin 16A passing through an upper leg 28A of a base piece angle 28 and leg 24A of angle piece 24, with a swaged end 26B capturing the leg 28A and several interposed friction discs 30 clamped together.

The swaged end 26B creates a tight connection so as to hold the upright member 12 in any adjusted inclination.

The base piece angle 28 has a bottom leg 28B overlying and held with screws to a molded plastic grid core piece 32 forming the base piece 14 shape seen with the bottom cover 39 removed (FIG. 8).

A top panel 34 (FIG. 8) defines the valley shape of the base piece 14 with padding covering the upper surface of the top panel 34A.

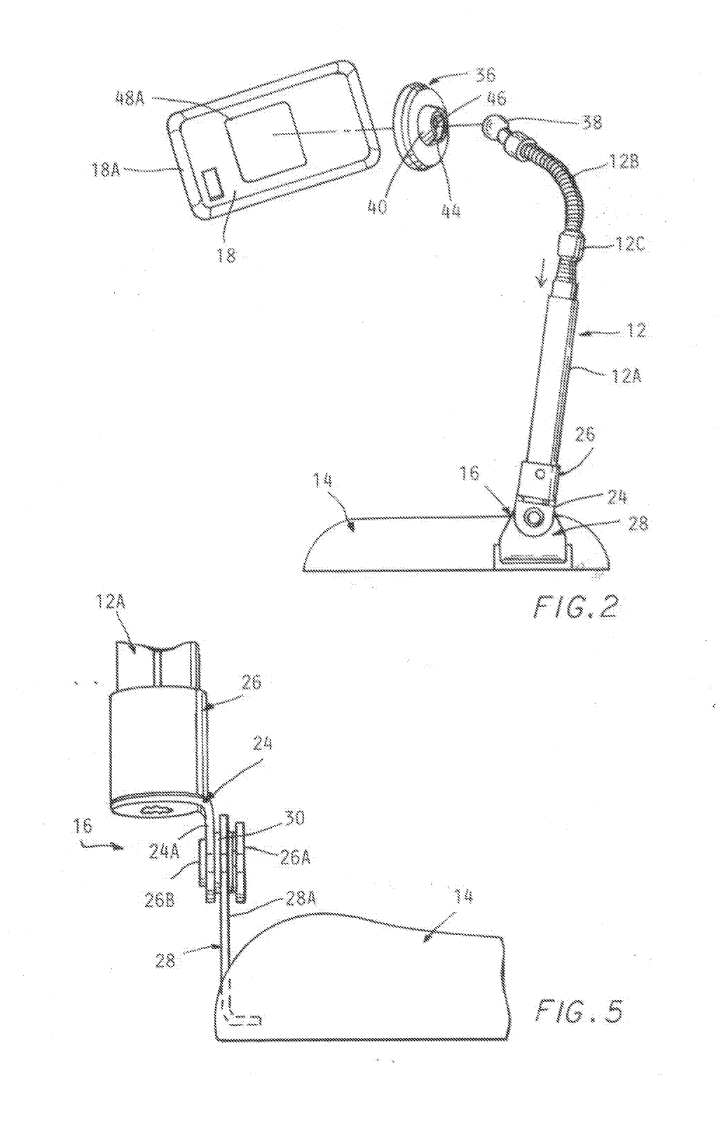

FIG. 2 shows the telescoped section 12A in the retracted state with a round magnetic cradle 36 detached from a ball element 38 connected to the upper end of the gooseneck section 12B.

The cradle 36 has a slotted socket 40 formed on one side able to snap fit the ball 38 therein. A shaft section 42 having the ball 38 attached is aligned with the slot 44 (FIG. 3) and the ball 38 pressed into a socket set 46 to create a ball connection which allows rotation of the electronic device 18 to any desired orientation.

A small metal plate 48 (FIG. 4) is attached with an adhesive sheet to the back of a smart phone electronic device 18A.

A larger metal plate 48A (FIG. 2) is used when a case 18A is installed on the device 18.

A clamping cradle 50 is shown in FIGS. 6 and 7, which has a pair of holding arms 52 which can be adjusted in or out to squeeze an electronic device 18. Support rests 50 hold the device 18 at the bottom. Such cradles are known in the art, and is described in U.S. Pat. No. 7,272,984.

A ball mount 54 is also provided for holding ball 38. A split threaded side receives the ball 38 when pressed thereon, with inwardly curved ends of segments 56 capturing the ball 38.

A threaded retainer nut 58 is threaded onto socket after the ball 38 has been pressed therein by spreading the segments 56. The nut 58 prevents spreading of the segments so as to prevent the ball 38 from covering out of the socket defined by segments 56.

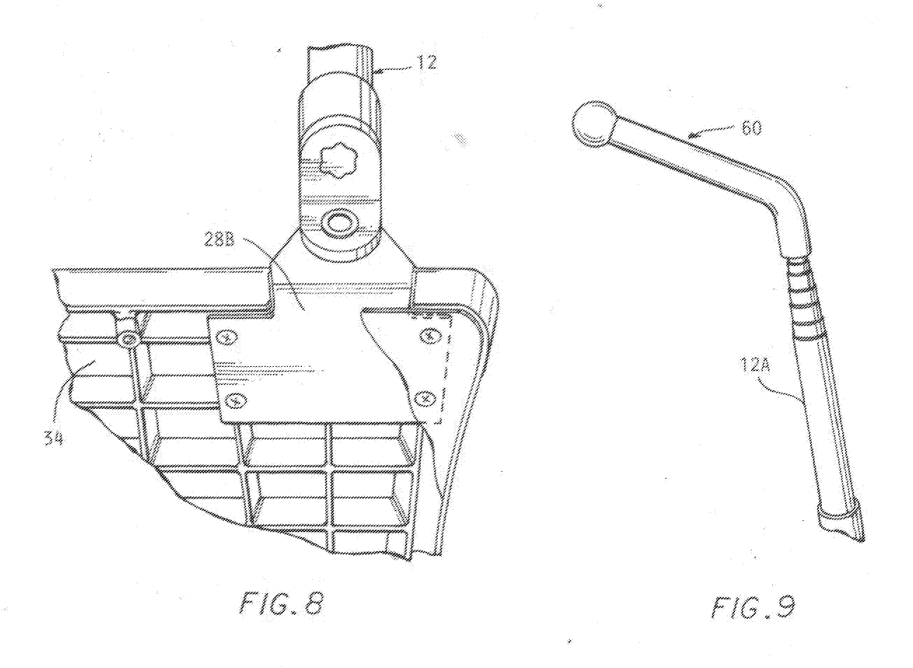

FIG. 9 shows an alternative embodiment in which an angled rigid arm 60 is coupled to the upper end of the telescoping section 12A so as to be able to be swung around.

Some reduction in the positioning capability results, but the rigid arm will be more durable if more important if a great deal of use is anticipated.

Other alternatives for the gooseneck 12B may be employed.

1. An elevating support for holding handheld electronic devices which include a display to be viewed by the user such as a smart phone or tablet, comprising:
a base piece configured to be able to be held beneath the thigh of a seated user or supine reclining user to be secured in that location;
an upright elongated member pivotally connected to said base piece extending upwardly from a side of said base piece so as to able to be swung by the user in a plane alongside said base piece towards and away from a seated user or alternatively above a reclining user in location where the display can best be viewed, with a holding feature of said pivotal connection causing said upright member to be held in any location to which it may be swung by the user; and
a cradle having a readily detachable attachment to an upper portion of said upright member so as to be able to be held selectively positioned within a range of said swinging motion to thereby allow the user to position said cradle at a desired location within said range of swinging motion including a plurality of sections telescoped together able to be moved in and out of each other and to remain in a varied adjustment by frictional engagement therebetween.

2. The support according to claim 1 wherein said support member includes a telescoping section enabling selective lengthening of said member to allow selective varying of the height of said cradle and an electronic device held therein.

3. The support according to claim 2 wherein said telescoping section is located at a bottom segment of said upright member adjacent said pivotal connection to said base piece.

4. The support according to claim 3 wherein said upright support also includes a gooseneck segment connected to said telescoping segment allowing bending anywhere along the length thereof.

5. The support according to claim 4 further including a ball and socket connection between said cradle and an upper end of said gooseneck segment.

6. The support according to claim 1 wherein said readily detachable attachment of said cradle to said upright member includes a plate holding one or more magnetic elements beneath a flat surface thereof and a metal plate attached to either a back surface of said electronic device or a back surface of a case for said electronic device to be attracted and held by magnetic attracted to said metal plate to thereby hold said electronic device onto said cradle.

7. The support according to claim 1 wherein said cradle comprises of clamping unit having space apart gripper arms which are able to be moved towards and away from each other to grip sides of said electronic device to engage and hold said electronic device therebetween.

8. The support according to claim 1 wherein said base piece comprises a padded upper surface on which a user's leg is supported.

9. The support according to claim 8 wherein said base piece is generally rectangular and has approximately seven inch sides.

10. The support according to claim 9 wherein said base piece includes a curved valley recess extending along the top able to receive a user's leg parallel to said plane of swinging motion of said upright arm.

11. The support according to claim 10 wherein said front and rear sides have curved recesses formed therein to accommodate a bent knee of the user.

12. A method of supporting an electronic device having an electronic display at an elevated level forward of a user comprising mounting an elongated upright support member to project up from a base piece planar configured to allow a user's thigh to rest thereon and thereby retain said elongated upright support in an upright and forward inclination orientation relative said base piece;
mounting a cradle able to detachably hold an electronic device adjacent an upper end of said support member to thereby enable securement of said electronic device in an elevated position in front of a seated user or alternatively above a reclining user in a readily viewed location.

13. The method according to claim 12 further including pivoting said upright member to a side of said base piece to allow swinging said upper member in a plane alongside said base member to be able to be oriented in any inclination forward of a seated user or above a reclining user to position said electronic device at selected locations so as to be easily viewed by user, further including holding said upright member in any selected inclination thereof.

14. The method according to claim 13 further including providing a telescoping section comprising at least a section of said elongate member to enable a selective height to be set to obtain a desired height position of said electronic device.

15. The method according to claim 14 including also including mounting a gooseneck to said telescoping section to comprise an upper segment of said elongated member to provide additional adjustment capability as an aid to the adjustment of the position of said electronic device.

16. The method according to claim 13 further including mounting said electronic device to a cradle at an upper end of said elongated member by a ball joint to enable reorienting said electronic device on said elongate member.
